(19) United States
(12) Patent Application Publication
(10) Pub. No.: US 2008/0000518 A1
(43) Pub. Date: Jan. 3, 2008

(54) Technique for Manufacturing Photovoltaic Modules

(76) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 11/692,806

(22) Filed: Mar. 28, 2007

Related U.S. Application Data
(60) Provisional application No. 60/786,902, filed on Mar. 28, 2006.

(51) Int. Cl. H01L 31/055; H01L 31/048

(52) U.S. Cl. 136/247

(57) ABSTRACT

The present invention, in one aspect, is directed to methods for manufacturing solar or photovoltaic modules for better environmental stability. In another aspect, the present invention is directed to environmentally stable solar or photovoltaic modules. These method and apparatus use a moisture barrier film to form a moisture-resistant surface on the circuit, preferably on an illuminating surface of solar cells, or an entire side of a circuit formed of a plurality of solar cells that includes the illuminating surface of solar cells. In certain embodiments, the moisture-resistant film is applied conformally, and in other embodiments the moisture-resistant film is substantially transparent.

### CLAIM OF PRIORITY

This application claims priority to and incorporates by reference herein U.S. Provisional Appln. Ser. No. 60/786,902 filed Mar. 28, 2006 entitled “Technique For Manufacturing Photovoltaic Modules.”

### FIELD OF THE INVENTION

The present invention relates to method and apparatus for manufacturing solar or photovoltaic modules for better environmental stability.

### BACKGROUND

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Amorphous Si [a-Si], cadmium telluride [CdTe] and copper-indium-(sulfo)selenide [CIGS(S), or Cu(In,Ga)(S,Se)₂ or CuIn₍₁₋ₓ₎Gaₓ(S_{y}Se_{(1-y)})ₖ, where 0≦x≦1, 0≦y≦1 and k is approximately 2], are the three important thin film solar cell materials. The structure of a conventional Group IBIIIAVIA compound photovoltaic cell such as a CIGS(S) thin film solar cell is shown in FIG. 1. The device 10 is fabricated on a substrate 11, such as a sheet of glass, a sheet of metal, an insulating foil or web, or a conductive foil or web. The absorber film 12, which comprises a material in the family of Cu(In,Ga,Al)(S,Se,Te)₂, is grown over a conductive layer 13 or a contact layer, which is previously deposited on the substrate 11 and which acts as the electrical ohmic back contact to the device. The most commonly used contact layer or conductive layer 13 in the solar cell structure of FIG. 1 is molybdenum (Mo). If the substrate itself is a properly selected conductive material such as a Mo foil, it is possible not to use a conductive layer 13, since the substrate 11 may then be used as the ohmic contact to the device. The conductive layer 13 may also act as a diffusion barrier in case the metallic foil is reactive. For example, foils comprising materials such as Al, Ni, Cu may be used as substrates provided a barrier such as a Mo layer, a W layer, a Ru layer, a Ta layer etc., is deposited on them protecting them from Se or S vapors. The barrier is often deposited on both sides of the foil to protect it well. After the absorber film 12 is grown, a transparent layer 14 such as a CdS, transparent conductive oxide (TCO) such as ZnO or CdS/TCO stack is formed on the absorber film. Radiation, R, enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1.

Solar cells have relatively low voltage of typically less than 2 volts. To build high voltage power supplies or generators, solar cells are interconnected to form circuits which are then packaged into modules. There are two ways to interconnect thin film solar cells to form circuits and then fabricate modules with higher voltage and/or current ratings. If the thin film device is formed on an insulating surface, monolithic integration is possible. In monolithic integration, all solar cells are fabricated on the same substrate and then integrated or interconnected on the same substrate by connecting negative terminal of one cell to the positive terminal of the adjacent cell (series connection). A monolithically integrated Cu(In,Ga,Al)(S,Se,Te)₂ compound thin film circuit structure 20 comprising series connected cell sections 18 is shown in FIG. 2A. In this case the contact layer is in the form of contact layer pads 13a separated by contact isolation regions or contact scribes 15. The compound thin film is also in the form of compound layer strips 12a separated by compound layer isolation regions or compound layer scribes 16. The transparent conductive layer, on the other hand, is divided into transparent layer islands 14a by transparent layer isolation regions or transparent layer scribes 17. As can be seen in FIG. 2A, the contact layer pad 13a of each cell section 18 is electrically connected to the transparent layer island 14a of the adjacent cell section. This way voltage generated by each cell section is added to provide a total voltage of V from the circuit structure 20.

The second way of integrating thin film solar cells into circuits is to first fabricate individual solar cells and then interconnect them through external wiring. This approach is not monolithic, i.e. all the cells are not on the same substrate. FIG. 2B schematically shows integration of three CIGS(S) solar cells 10 into a circuit 21 section, wherein the CIGS(S) cells 10 may be fabricated on conductive foil substrates with a structure similar to the one depicted in FIG. 1.

Irrespective of the integration approach used, after the solar cells are electrically interconnected into a circuit such as the circuit 21 shown in FIG. 2B, the circuit needs to be packaged to form an environmentally stable and physically well-protected product which is a module. FIG. 3 shows an exemplary form of a package after the integrated cells of FIG. 2B are encapsulated in a protective package. The structure in FIG. 3 is a flexible module structure that is very attractive in terms of its flexibility and light weight. Some of the commonly used layers in the structure of FIG. 3 are a top film 30, a flexible encapsulant 31, and a backing material 32. The top film 30 is a transparent durable layer such as TEFZEL® manufactured by DuPont. The most commonly used flexible encapsulant is slow cure or fast cure EVA (ethyl vinyl acetate). The backing material 32 may be a TEFZEL® film, a TEDLAR® film (produced by DuPont) or any other polymeric film with high strength. It should be noted that since the light enters from the top, the backing material 32 does not have to be transparent and therefore it may comprise inorganic materials such as metals.

Although desirable and attractive, the flexible thin film photovoltaic module of FIG. 3 may have the drawback of environmental instability. Specifically, the commercially available and widely used top films and flexible encapsulants are semi-permeable to moisture and oxygen therefore corrosion and cell deterioration may be observed after a few years of operation of the flexible module in the field. Therefore, there is a need to develop alternative packaging techniques for modules to provide resistance to moisture absorption and diffusion to the active regions of the circuit.

### SUMMARY OF THE INVENTION

The present invention, in one aspect, is directed to methods for manufacturing solar or photovoltaic modules for better environmental stability.

The present invention, in another aspect, is directed to environmentally stable solar or photovoltaic modules.

In a particular embodiment, there is described a method of manufacturing a photovoltaic module by providing at least two solar cells, each of the at least two solar cells having a top illuminating surface and two terminals. There then follows the steps of electrically interconnecting the at least two solar cells with a conductor between at least one of the terminals of each of the at least two solar cells to form a circuit, and coating at least an entire side of the circuit that corresponds to and includes the top illuminating surface of the at least two solar cells with a moisture barrier film to form a moisture-resistant surface on the circuit.

In another embodiment, there is described a method of manufacturing a photovoltaic module that includes coating at least an illuminating surface of solar cells with a moisture barrier film to form solar cells with moisture-resistance; electrically interconnecting any two of the solar cells using a conductor between at least one of the terminals of each of the any two solar cells to form a circuit, and encapsulating the circuit in a package.

In a further embodiment, described is a module that includes at least two solar cells, each of the at least two solar cells having a top illuminating surface and two terminals; an electrical conductor that electrically interconnects the at least two solar cells with a conductor between at least one of the terminals of each of the at least two solar cells, and a moisture barrier film that coats at least an entire side of the circuit that corresponds to and includes the top illuminating surface of the at least two solar cells to form a moisture-resistant surface on the circuit.

In a further embodiment, described is a module that includes at least two moisture-resistant solar cells each having an illuminating surface that is coated with a moisture barrier film; a conductor that electrically interconnects any two of the moisture-resistant solar cells using a conductor between at least one of the terminals of each of the any two moisture-resistant solar cells to form a circuit, and encapsulating materials that encapsulates the circuit in a package.

In certain embodiments, the moisture-resistant film is applied conformally, and in other embodiments the moisture-resistant film is substantially transparent.

### BRIEF DESCRIPTION OF THE DRAWINGS

These and other aspects and features of the present invention will become apparent to those of ordinary skill in the art upon review of the following description of specific embodiments of the invention in conjunction with the accompanying figures, wherein:

FIG. 1 is a cross-sectional view of a solar cell employing a Group IBIIIAVIA absorber layer.

FIG. 2A is a cross-sectional view of a circuit obtained by monolithic integration of solar cells.

FIG. 2B is a cross-sectional view of a circuit obtained by non-monolithic integration of solar cells.

FIG. 3 shows a module structure obtained by encapsulating the circuit of FIG. 2B in a protective package.

FIGS. 4A and 4B show solar cells first coated with a transparent moisture barrier layer and then integrated into a circuit according to two different embodiments of the invention.

FIGS. 5A and 5B show solar cells first integrated into a circuit and then coated with a transparent moisture barrier layer according to two different embodiments of the invention.

FIG. 6 shows a module structure obtained by encapsulating the circuit of FIG. 5A.

### DETAILED DESCRIPTION

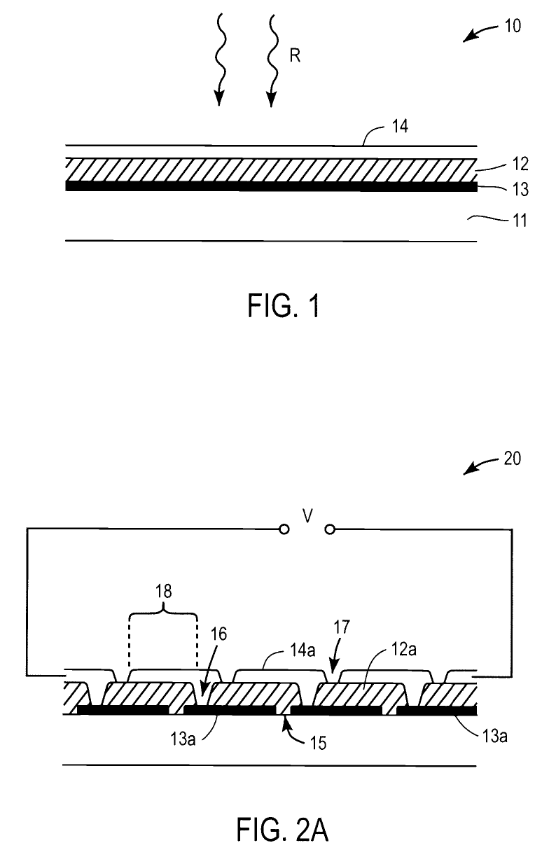

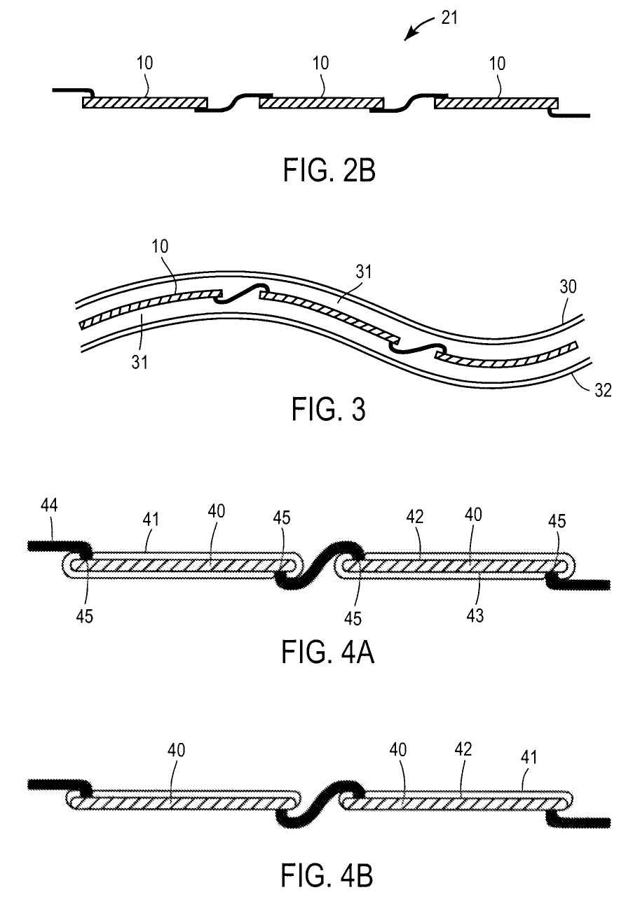

In one embodiment of the present invention, each solar cell in the circuit is individually covered by a transparent moisture barrier material layer before the cells are integrated into circuits and then packaged into modules. FIG. 4A shows two exemplary CIGS(S) solar cells 40 with all the components and layers indicated in FIG. 1. For example, the solar cells 40 may be fabricated on flexible foil substrates i.e. substrate 11 of FIG. 1 may be a metallic foil. The solar cells 40 are covered by a transparent moisture barrier material layer 41, which as shown in FIG. 4A covers the entire cell 40 including top and bottom surfaces, and in FIG. 4B covers the top illuminating surface 42 of the cell where the light enters the device. This top illuminating surface 42 is the most sensitive surface to protect from moisture and in some cases oxygen. The transparent moisture barrier material layer 41 may optionally wrap around to the back surface 43 of the foil substrate as shown in FIG. 4A. After obtaining the moisture barrier-covered solar cells, integration or interconnection is carried out as shown in FIG. 2B using metallic ribbons or wires 44. For interconnection, the (−) terminal of one cell is electrically connected to the (+) terminal of the other one. This can be achieved through use of soldering wires or ribbons as shown in FIG. 4A. Alternately the cells maybe directly interconnected by overlapping their respective edges and electrically connecting the front electrode of one cell (which is the negative terminal in the case of the device structure shown in FIG. 1) with the back electrode of the next one. It should be noted that if the barrier material layer 41 is highly insulating and thick it should be at least partially removed from the connection points 45 so that good electrical contact may be obtained between the cell electrode and the ribbon or wire.

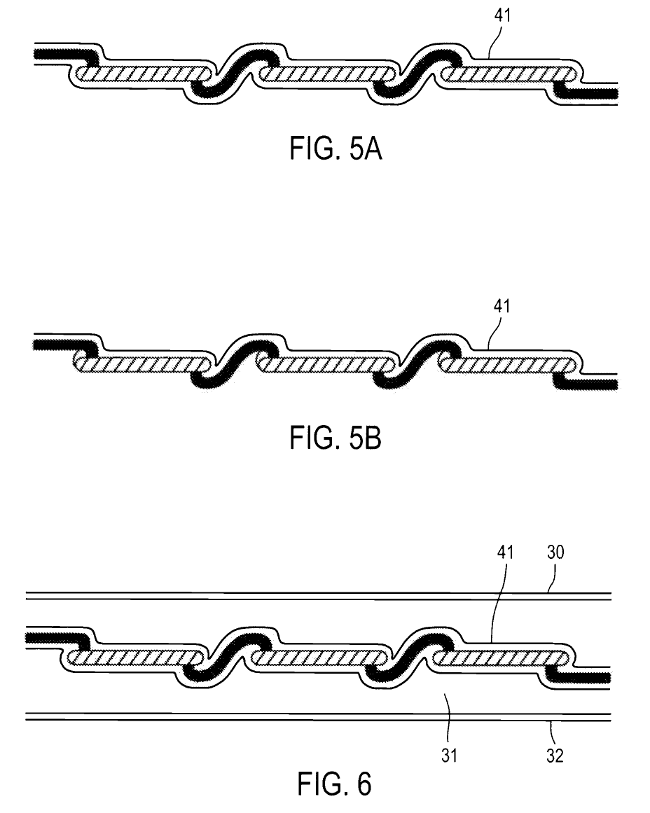

In another approach shown in FIGS. 5(a) and 5(b), the solar cells are first electrically interconnected with a conductor, such as through soldering wires or ribbons, to form a circuit like the one shown in FIG. 2B, and then the whole circuit is covered with a transparent moisture barrier material layer 41, the moisture barrier material 41 either covering the entire circuit, top and bottom, as illustrated in FIG. 5A or as illustrated in FIG. 5B, covering only the side of the circuit that contains the top surface where light enters the device. Some of the advantages of this approach are: i) Since the cells are already interconnected, the step of removing the barrier material layer from the connection points is avoided, ii) since the moisture barrier material layer is deposited after interconnection of the solar cells, the barrier material layer covers all portions of the circuit including the connection points and ribbons or wires. The approach as shown in FIG. 5A provides total encapsulation or coverage by the moisture barrier layer around the entire circuit, whereas encapsulation and coverage are provided in the FIG. 5B approach on that side where such protection is most needed. Either approach reduces the possibility of moisture or oxygen diffusion through any crack or opening.

After the circuit is covered by at least one transparent moisture barrier material layer, the structure obtained is a moisture resistant circuit (FIGS. 4A and 4B and FIGS. 5A and 5B). The modules may then be fabricated by various methods such as encapsulating the moisture resistant circuits by a top film 30, an encapsulant 31 and a backing material 32 as shown in FIG. 6. The flexible module obtained by such an approach has a moisture resistant circuit within the module packaging and therefore is environmentally much more stable. It should be noted that use of a backing material 32 is optional in this case. Also the moisture barrier capability of the top film and the backing material is not as important in the module structure of FIG. 6 compared to the structure of FIG. 3, because of the presence of a transparent moisture barrier layer 41 encapsulating the whole circuit. It should also be noted that the transparent moisture barrier layers may also be used to coat the monolithically integrated structures similar to that shown in FIG. 2A before such monolithically integrated circuits are packaged to form modules.

The transparent moisture barrier material layer may comprise at least one of an inorganic material and a polymeric material. Polyethylene, polypropylene, polystyrene, poly(ethylene terephthalate), polyimide, parylene or poly(chloro-p-xylylene), BCB or benzocyclobutene, polychlorotrifluoroethylene are some of the polymeric materials that can be used as moisture and oxygen barriers. Various transparent epoxies may also be used. Inorganic materials include silicon or aluminum oxides, silicon or aluminum nitrides, silicon or aluminum oxy-nitrides, amorphous or polycrystalline silicon carbide, other transparent ceramics, and carbon doped oxides such as SiOC. These materials are transparent so that when deposited over the transparent conductive contact of the solar cell they do not cause appreciable optical loss. It should be noted that polymeric and inorganic moisture barrier layers may be stacked together in the form of multi-layered stacks to improve barrier performance. Layers may be deposited on the solar cells or circuits by a variety of techniques such as by evaporation, sputtering, e-beam evaporation, chemical vapor deposition (CVD), plasma-enhanced CVD (PECVD), organometallic CVD, and wet coating techniques such as dipping, spray coating, doctor blading, spin coating, ink deposition, screen printing, gravure printing, roll coating etc. It is also possible to melt some of the polymeric materials at temperatures below 200 C, preferably below 150 C and coat the melt on the cells and circuits. Thickness of the moisture barrier layers may vary from 50 nm to several hundred microns. One attractive technique is vapor deposition which has the capability of conformal and uniform deposition of materials such as parylene. Parylene has various well known types such as parylene-N, parylene-D and parylene-C. Especially parylene-C is a good moisture barrier that can be vapor deposited on substrates of any shape at around room temperature in a highly conformal manner, filling cracks and even the high aspect ratio (depth-to width ratio) cavities of submicron size effectively. Thickness of parylene layer may be as thin as 50 nm, however for best performance thicknesses higher than 100 nm may be utilized. Another attractive method for depositing moisture barrier layers is spin, spray or dip coating, which, for example may be used to deposit barrier layers of low temperature curable organosiloxane such as P1DX product provided by Silecs corporation. PECVD is another method that may be used to deposit layers such as BCB layers.

Although the present invention is described with respect to certain preferred embodiments, modifications thereto will be apparent to those skilled in the art.

I claim:

1. A method of manufacturing a photovoltaic module comprising;
providing at least two solar cells, each of the at least two solar cells having a top illuminating surface and two terminals;
electrically interconnecting the at least two solar cells with a conductor between at least one of the terminals of each of the at least two solar cells to form a circuit, and
coating at least an entire side of the circuit that corresponds to and includes the top illuminating surface of the at least two solar cells with a moisture barrier film to form a moisture-resistant surface on the circuit.

2. The method according to claim 1 wherein the step of coating fully encapsulates the circuit with the moisture barrier film.

3. The method according to claim 2 wherein the step of coating coats the moisture barrier film conformally.

4. The method according to claim 3 further including the steps of embedding the circuit having the moisture-resistant surface within a structure comprising a top film, a flexible encapsulant and a backing material.

5. The method according to claim 2 wherein the moisture barrier film is substantially transparent to solar light.

6. The method according to claim 5 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

7. The method according to claim 1 wherein the step of coating coats the moisture barrier film conformally.

8. The method according to claim 7 further including the steps of embedding the circuit having the moisture-resistant surface within a structure comprising a top film, a flexible encapsulant and a backing material.

9. The method according to claim 1 wherein the moisture barrier film is substantially transparent to solar light.

10. The method according to claim 9 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

11. The method according to claim 1 wherein the step of electrically interconnecting interconnects a chain of at least three solar cells, such that each solar cell is electrically connected to at least one other solar cell.

12. A method of manufacturing a photovoltaic module comprising;
coating at least an illuminating surface of solar cells with a moisture barrier film to form solar cells with moisture-resistance;
electrically interconnecting any two of the solar cells using a conductor between at least one of the terminals of each of the any two solar cells to form a circuit, and
encapsulating the circuit in a package.

13. The method according to claim 12 wherein the step of coating coats substantially all surfaces of the solar cells including the illuminating surface and the back surface, with the moisture barrier film, and
wherein the step of electrically interconnecting includes the step of forming an opening in the moisture barrier film so that the conductor can form the electrical interconnection at the at least one of the terminals of each of the at least two solar cells.

14. The method according to claim 13 wherein the moisture barrier film is substantially transparent to solar light.

15. The method according to claim 14 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

16. The method according to claim 13 wherein the step of encapsulation comprises embedding the circuit within a structure that includes a top film, a flexible encapsulant and a backing material.

17. The method according to claim 12 wherein the step of encapsulation comprises embedding the circuit within a structure that includes a top film, a flexible encapsulant and a backing material.

18. The method according to claim 12 wherein the moisture barrier film is substantially transparent to solar light.

19. The method according to claim 18 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

20. The method according to claim 12 wherein the step of electrically interconnecting interconnects a chain of at least three solar cells, such that each solar cell is electrically connected to at least one other solar cell.

21. A photovoltaic module comprising;
at least two solar cells, each of the at least two solar cells having a top illuminating surface and two terminals;
an electrical conductor that electrically interconnects the at least two solar cells with a conductor between at least one of the terminals of each of the at least two solar cells, and
a moisture barrier film that coats at least an entire side of the circuit that corresponds to and includes the top illuminating surface of the at least two solar cells to form a moisture-resistant surface on the circuit.

22. The module according to claim 21 wherein the moisture-barrier film fully encapsulates the circuit.

23. The module according to claim 22 wherein the moisture barrier film is coated conformally.

24. The module according to claim 23 further including a structure in which the circuit that contains the top illuminating surface is embedded, the structure including a top film, a flexible encapsulant and a backing material.

25. The module according to claim 22 wherein the moisture barrier film is substantially transparent to solar light.

26. The module according to claim 25 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

27. The module according to claim 21 wherein the moisture barrier film is coated conformally.

28. The module according to claim 27 further including a structure in which the circuit that contains the top illuminating surface is embedded, the structure including a top film, a flexible encapsulant and a backing material.

29. The module according to claim 21 wherein the moisture barrier film is substantially transparent to solar light.

30. The module according to claim 29 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

31. The module according to claim 21 wherein at least three solar cells are interconnected in a chain, such that each solar cell is electrically connected to at least one other solar cell.

32. A photovoltaic module comprising;
at least two solar cells each having an illuminating surface that is coated with a moisture barrier film;
a conductor that electrically interconnects any two of the moisture-resistant solar cells using a conductor between at least one of the terminals of each of the any two solar cells to form a circuit, and
a package within which the circuit is embedded.

33. The module according to claim 32 wherein the substantially all surfaces of the solar cells are coated with the moisture barrier film.

34. The module according to claim 33 wherein the moisture barrier film is substantially transparent to solar light.

35. The module according to claim 34 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

36. The module according to claim 33 wherein the package includes a top film, a flexible encapsulant and a backing material.

37. The module according to claim 32 wherein the package includes a top film, a flexible encapsulant and a backing material.

38. The module according to claim 32 wherein the moisture barrier film is substantially transparent to solar light.

39. The module according to claim 38 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.

40. The module according to claim 32 wherein at least three solar cells are interconnected in a chain, such that each solar cell is electrically connected to at least one other solar cell.
